(19) United States
(12) Patent Application Publication
(10) Pub. No.: US 2019/0177851 A1
(43) Pub. Date: Jun. 13, 2019

(54) SYSTEM AND METHOD FOR GAS PHASE DEPOSITION

(71) Applicant: Singulus Technologies AG, Kahl am Main (DE)

(72) Inventors: Alexey IVANOV, Aachen (DE); Andreas KLEPL, Aschaffenburg (DE); Johannes RICHTER, Dieburg (DE)

(73) Assignee: Singulus Technologies AG, Kahl am Main (DE)

(21) Appl. No.: 16/323,731

(22) PCT Filed: Jun. 27, 2017
(86) PCT No.: PCT/EP2017/065829

§ 371 Date: Feb. 6, 2019

(30) Foreign Application Priority Data
Aug. 9, 2016 (EP) 16183400.7

(51) Int. Cl. C23C 16/52; C23C 16/458; C23C 16/455; C23C 16/46

(52) U.S. Cl. CPC C23C 16/52; C23C 16/4584; C23C 16/46; C23C 16/4557; C23C 16/45574

(57) ABSTRACT

A system for gas phase deposition comprises a gas injector configured to process gases to a substrate for gas phase deposition onto the substrate. The gas injector comprises a first flow path and a second flow path different from the first flow path. The system comprises a first temperature adjustment mechanism associated with the first flow path to control a temperature of a process gas passing through the first flow path. The system comprises a second temperature adjustment mechanism associated with at least the second flow path to control a temperature of a process gas passing through the second flow path. The first temperature adjustment mechanism and the second temperature adjustment mechanism are operable independently of each other. The system is configured to cause rotation and levitation of the substrate during etching of the substrate and/or deposition.

### BACKGROUND

### 1. Field of the Disclosure

The present disclosure relates to systems and methods for gas phase deposition onto a substrate. The disclosure relates in particular to systems and methods in which a gas injector directs a process gas onto a surface of a substrate.

### 2. Discussion of the Background Art

Gas phase deposition of material onto a substrate is used for controlled growth and has a wide variety of applications. Gas phase deposition may be used in techniques such as Metalorganic Vapour Phase Epitaxy (MOVPE) or Metalorganic Chemical Vapour Deposition (MOCVD), which can be used for epitaxy. In general, gas phase deposition techniques utilize transport of material towards the substrate surface via free space of pipes, channels and/or reactor volume. Thus, it differs from Liquid Phase Epitaxy (LPE) and Solid Phase Epitaxy or Crystallization. Additional energy may be provided to a surface of a substrate, for example in the form of heat, light or plasma, to trigger chemical reactions required to decompose the precursors containing specific components and/or enable synthesis of a desired compound directly on the substrates surface.

Gas phase deposition is frequently implemented in such a manner that only the growing surface of the substrate is provided with energy, e.g. by heating, while all other apparatus components remain cold, i.e., are not energized. Thereby, the risk of contamination of open surfaces other than the substrate surface on which deposition is to be performed may be mitigated. The risk of a drift of physical characteristics of the apparatus and of uncontrollable contamination by gases such as O₂, H₂O, etc. and particles, such as pieces of coating layer delaminating from the open surfaces of the substrate and the growing layer may also be mitigated thereby.

U.S. Pat. No. 5,551,985 A discloses a Chemical Vapour Deposition (CVD) reactor which includes a vacuum chamber having first and second thermal plates disposed therein and two independently-controlled multiple-zone heat sources disposed around the exterior thereof. The first heat source has three zones and the second heat source has two zones. A wafer to be processed is positioned below the first thermal plate and immediately above the second thermal plate. Nozzles are arranged on lateral sides of a substrate, effecting a horizontal flow of gas through the reactor.

U.S. Pat. No. 4,836,138 A discloses a heating system for use in a chemical vapor deposition equipment of the type wherein a reactant gas is directed in a horizontal flow for depositing materials on a substrate which is supported in a reaction chamber on a susceptor which is rotatably driven for rotating the substrate about an axis which extends normally from its center.

By nature, different process gases require different energy to get partially or completely decomposed. Therefore, any particular process temperature or other energizing process can be optimized for one reactant or precursor only. Additionally, a certain energy is required to achieve sufficient mobility of ad-atoms on the substrate surface to form a high quality layer and to reach activation energy for a particular synthesis reaction. The latter energy is related to evaporation energy, which defines the highest temperature for a given synthesis reaction. The same holds true for the substrate material, which might get decomposed or partly evaporated if the temperature exceeds a certain threshold level.

While, in order to ensure that a layer of high quality can be formed, the optimum substrate temperature should not be too low, it should not be too high, either, because this may lead to a rough growing surface.

Gas phase deposition systems and methods which allow only the substrate temperature to be set to provide energy for precursor decomposition, synthesis reaction, and/or alignment of ad-atoms on the substrate surface may have shortcomings because the set temperature may not be optimum for at least one of these processes. For illustration, one or several of the following shortcomings may be encountered: (1) Nucleation layer growth may have to be performed at a temperature lower than the temperature that would result in the best layer quality, because, for example, higher temperatures would reduce adhesion of atoms on the substrate surface to an unacceptable degree and/or because higher temperatures might destroy the arrangement of atoms and lead to a rough or even amorphous surface, where a grown layer will not be capable of inheriting a proper crystalline structure. Inter-diffusion between components of the substrate and grown layer may also occur at temperatures which would be optimum for other purposes. This may lead, in a simple case, to interfaces which are not sharp or to a degradation of the whole structure due to possible physicochemical reactions on the interface. (2) The growth of certain compounds may have to be performed at a temperature which is lower than a temperature that would be optimum for precursor decomposition and reaction. A reason for this may be that the evaporation or decomposition energy of the compounds is low. High diffusion coefficients or clustering formation are other phenomena which may require the temperature to be set to a value lower than the temperature that would be optimum for precursor decomposition and reaction. (3) In order to address the preceding issue (2), an oversupply of one or several precursor components may be employed. This may in turn promote gas phase reactions of the components, which may deteriorate the surface and, thus, the layer quality because amorphous clusters or even particles may be coated onto the grown layer. Precursor efficiency may also be reduced significantly, leading to lower growth rate and/or requiring comparatively larger amounts of material. The oversupply of one or several precursor components may also create parasitic deposition on surfaces other than the substrate surface, which is undesirable because it may necessitate more frequent cleaning operations. (4) A higher precursor consumption of only a single precursor or a sub-set of precursors may necessitate flow balance compensation with a carrier gas, thus increasing overall gas consumption. This in turn may increase process costs. (5) In order to ensure high layer quality, the temperature of the substrate surface may need to be increased to the highest possible value for the respective substrate and/or process etc. that is still commensurate with the other process requirements, such as preventing excessive desorption. This may give rise to an increase in production costs. Further, use of such high substrate temperatures may have adverse effects on the substrate and/or may make it challenging to achieve a uniform temperature. (6) For various reasons, it may be undesirable to set the substrate temperature to fairly high values. These reasons include the negative impact of usually different thermal expansion coefficients between the layer or a stack of different layers and the substrate. During a cool down process, the grown structure might reveal cracks and overall shape deformation, rendering it unsuitable for further utilization.

Additional energy sources may be used for precursor activation. For illustration, a plasma source may be used to convert diatomic nitrogen (N₂) into mono-atomic nitrogen (N) to make it more reactive. This may allow, for example, an InN compound to be grown with high quality at low temperatures of approximately 500° C. A drawback of plasma activation is the requirement to work under low pressure conditions, e.g., pressures of about 10⁻² mbar. The short life time of ionized species may render plasma less efficient when it has to travel through longer distances, as is the case for remote plasma generation. The ballistic regime of active ions may lead to mechanical deterioration of the growing surface and the substrate in case of direct plasma and high oxygen content in the film, because of removal of adsorbed oxygen from surfaces of surrounding surfaces, mostly made of metals. While Plasma Enhanced Deposition (PED) processes may be beneficial, e.g., in case of oxide layers deposition, where oxygen impurity is not a problem, it may not be suitable for other deposition processes where oxygen is not desired.

In case of MBE (Molecular Beam Epitaxy) or PE-MBE (Plasma Enhanced MBE) most metal sources are used directly from effusion cells without necessity to break the bonds before synthesis reaction, although for some elements like nitrogen plasma activation may be required. The substrate temperature mainly defines the synthesis conditions, surface mobility of ad-atoms and possible evaporation. Many compounds of interest decompose rather at high temperatures with partial evaporation under low pressure conditions. Due to the ease of evaporation under vacuum conditions the temperature of MBE process may be subject to more severe limitations than higher pressure processes like CVD.

EP 1 033 743 A2 discloses a substrate processing apparatus, which has a gas ejection head for individually introducing at least two gases including a material gas and ejecting the gases toward a substrate to be processed. The gas ejection head has at least two gas passageways for individually introducing the two gases, and at least two temperature control devices for individually controlling temperatures of the gases flowing through the gas passageways.

US 2012/0097330 A1 discloses a substrate processing system, which includes a thermal processor or a plasma generator adjacent to a processing chamber. A first processing gas enters the thermal processor or plasma generator. The first processing gas then flows directly through a showerhead into the processing chamber. A second processing gas flows through a second flow path through the showerhead. The first and second processing gases are mixed below the showerhead and a layer of material is deposited on a substrate under the showerhead.

US 2003/0054099 A1 discloses a method for the production of coated substrates. At least one layer is deposited on at least one substrate, by means of a condensation method and a solid and/or fluid precursor.

There is still a need in the art for systems and methods that afford enhanced control over process parameters. There is in particular a need in the art for such systems and methods that allow a large fraction of the substrate area to be used and/or that mitigate the effects of undesired uncontrolled temperature variations along a substrate surface.

In view of the above, it is an object of the present disclosure to perform gas phase deposition in a manner which affords enhanced control over process parameters, such as temperatures or energies of the substrate surface and process gases. It is also an object of the present disclosure to mitigate at least some of the shortcomings of conventional techniques described above.

### SUMMARY

According to the present disclosure, different flow paths are provided which may be used for different reactants or precursors. A first group of process gases may be passed through a first flow path. A different second group of process gases may be passed through a second flow path. Temperature adjustment mechanisms that are operable independently of each other may be associated with the first and second flow paths, respectively.

For illustration, a temperature adjustment mechanism which may include a resistive heater, an inductive heater, a source of electromagnetic radiation or other thermal or optical heating mechanisms may be associated with the second flow path to control the temperature of the second group of process gases, in particular by heating the second group of process gases. Another temperature adjustment mechanism which may include a fluid circuit for a coolant or heating agent may be associated with the first flow path to control the temperature of the processes gases included in the first group of process gases, in particular by ensuring that the first group of process gases is maintained at a temperature lower than the second group of process gases when directed onto a growing surface of the substrate. The first flow path may, for example, consist of a hollow plate cooled by a coolant and having a shape matched to a shape of the substrate. A plurality of gas outlets, which may be formed by hollow pins, may each define a cavity for guiding the first group of process gases, may project from the hollow plate and may be cooled by coolant circulating through at least one duct of the hollow plate.

A system for gas phase deposition according to the present disclosure comprises a gas injector configured to guide process gases to a substrate for gas phase deposition onto the substrate. The gas injector comprises a first flow path and a second flow path different from the first flow path. The system comprises a first temperature adjustment mechanism associated with the first flow path to control a temperature of process gases passing through the first flow path. The system comprises a second temperature adjustment mechanism associated with at least the second flow path to control a temperature of process gases passing through the second flow path, the first temperature adjustment mechanism and the second temperature adjustment mechanism may be operable independently of each other. The system is configured to cause rotation and levitation of the substrate during etching of the substrate and/or during deposition.

Enhanced process control is attained by the gas phase deposition system, because the temperatures of two different groups of process gases supplied through the gas injector may be controlled independently using the first temperature adjustment mechanism and the second temperature adjustment mechanism.

As used herein, different first and second temperature adjustment mechanisms are considered to be operable independently of each other when the first temperature adjustment mechanism can provide a cooling or heating power that is adjustable independently of a heating or cooling power of the second temperature adjustment mechanism, so that the temperatures of the process gases passing through the different first and second flow paths may be controlled generally independently of each other, at least for the normal operating parameter ranges of the gas phase deposition system.

As used herein, the term first flow path refers to a portion of the gas injector which has formed therein at least one and preferably a plurality of channels to pass a first process gas to the substrate through the channel(s) of the first flow path. The term first flow path may in particular refer to a portion of the gas injector which has formed therein at least one and preferably a plurality of channels to pass a first group of process gases to the substrate through the channel(s) of the first flow path. The term second flow path refers to another portion of the gas injector which has formed therein at least one and preferably a plurality of channels to pass a second process gas to the substrate through the channel(s) of the second flow path. The term second flow path may in particular refer to a portion of the gas injector which has formed therein at least one and preferably a plurality of channels to pass a second group of process gases to the substrate through the channel(s) of the second flow path.

The first and second flow paths may both be arranged on the same side relative to the process area in which the substrate is positioned during deposition or etching.

The second temperature adjustment mechanism may, but does not need to be specifically dedicated for controlling the temperature of process gases passing through the second flow path. For illustration, the second temperature adjustment mechanism may be implemented by a heating mechanism which also heats the substrate from the top side. This heating mechanism may be placed in thermal contact with the second flow path for heating the process gases flowing through the second flow path. At the same time the thermal contact between heating mechanism and the substrate can be purposely weakened by adjusting, e.g. increasing, the geometrical gap between both. According to the experiments with a sufficiently large gap the temperature difference can reach 500° C. or more especially by using active cooling of substrate from other side.

The first and second temperature adjustment mechanisms may be based on different cooling or heating techniques. For illustration, the first temperature adjustment mechanism may comprise a source of coolant or heating agent configured to circulate the coolant or heating agent through at least one duct of the first flow path, to thereby control the temperature of a first process gas flowing through the first flow path. The second temperature adjustment mechanism may comprise a resistive heater, an inductive heater, a source of electromagnetic radiation, e.g., a laser source, or other heating mechanisms.

The system may further comprise a third temperature adjustment mechanism configured to heat or cool the substrate from the other side.

The third temperature adjustment mechanism may be operable independently of the first temperature adjustment mechanism and the second temperature adjustment mechanism. Further improved process control is attained thereby.

The second temperature adjustment mechanism may be configured to heat the substrate from a first surface and the third temperature adjustment mechanism may be configured to heat or cool the substrate from a second surface, the second surface being opposite the first surface. The active cooling mechanism can be based on utilization of purging gas with high thermal conductivity like hydrogen in case of non-contact substrate placement on top of a base. For the contact substrate placement or for active cooling of a base the standard water/oil cooling can be utilized.

The second and third temperature adjustment mechanisms may respectively be arranged so as to be spaced from the substrate. Such a space can be changed in-situ during the running process by corresponding mechanism or adjusted upfront as one of the system configuration parameter.

The system may comprise a control unit configured to control at least one of the first, second and third temperature adjustment mechanisms as a function of time in a manner coordinated with a time-dependent variation of a process gas flow through the first flow path. Thereby, a spike deposition may be implemented in which higher layer quality may be attained at average lower substrate temperature.

The third temperature adjustment mechanism may comprise a substrate bottom heater. The control unit may be configured to control the temperature of the substrate bottom heater as a function of time in a manner coordinated with a time-dependent variation of a flow of a process gas through the first flow path.

The substrate bottom heater and a heater of the second temperature adjustment mechanism may be arranged such that the substrate is receivable in a space between the bottom heater and the heater of the second temperature adjustment mechanism. The system may be configured such that no components of the system are arranged in between the substrate bottom heater and the substrate and that no components of the system are arranged in between the heater of the second temperature adjustment mechanism and the substrate.

The first flow path may comprise a plurality of projections. The projections may be arranged normally to the substrate surface or inclined. In the case of inclined arrangement, the angle of inclination for each projection may vary. In a particular case, the arrangement can be made helical where the inclination angle may vary with a distance from the center in case of symmetrical or in a particular case round shape. An advantage of inclined, e.g. helical, arrangement is a more stable flow pattern, an elongated path to the substrate providing better intermixing between two groups of precursors and reduced turbulence at high flow rate near the substrate surface. Each one of the plurality of projections may respectively have an internal cavity extending along a longitudinal axis to pass a process gas through the respective projection and an outlet opening. The projections may respectively be hollow pins.

The first flow path may further comprise a member having at least one internal cavity in communication with the cavities of the plurality of projections. The plurality of projections may project from a major face of the member and may be thermally coupled to the member. The member may be a hollow plate. The major face of the hollow plate may have a shape and size that is matched to, and which may be equal to, the shape and size of the substrate.

The projections may be gas outlets projecting from the member. The gas outlets may have an inner diameter of at least 0.1 mm and at most 1 mm. Alternatively or additionally, the gas outlets may be arranged on the major face of the member at a surface density of at least 0.1 cm⁻² and at most 20 cm⁻². The gas outlets may be pin-shaped or may have other shapes.

The gas outlets may have a polished inner surface. Adsorption and desorption processes may be reduced thereby. Alternatively or additionally, the gas outlets may have an outer surface which is polished or provided with a reflective coating. Reflection of thermal radiation may be reduced thereby, causing heat transfer from the second flow path to the first flow path to be reduced. The reflective coating may be a reflective metal coating, e.g., of Au (gold) or Al (aluminum), without being limited thereto.

Each gas outlet may have a heat jacket. The heat jacket may be formed of a sleeve or bushing which at least partially surrounds an outer surface of the gas outlet. The sleeve or bushing may be formed of a ceramic material or of another material having low thermal conductivity and/or ability to sustain high temperature over the long period of time.

The gas outlets may be arranged to have their output openings positioned at orifices formed in a heater of the second temperature adjustment mechanism. Each one of the gas outlets may be associated with a corresponding orifice in the heater.

A source of electromagnetic radiation, in particular a light source, may be comprised by or coupled to at least a subset of the gas outlets. The control unit of the system may control the source of electromagnetic radiation comprised by or attached to the gas outlets to measure substrate temperature remotely, e.g., by utilizing black (gray) body radiation effect or by using other physical effects like Raman scattering etc. By utilizing the active light source going through the same path the growth and/or etch rate of the layer can be established in-situ.

The provision of the gas outlets allows the first process gases, e.g., a mixture of carrier gas and a first group of reactants or first precursor(s), to reach and be passed through the heater of the second temperature adjustment mechanism without being significantly heated by the heater of the second temperature adjustment mechanism.

The first flow path may comprise at least one duct for a coolant or heating agent. The first temperature adjustment mechanism may be configured to pass the coolant or heating agent through the at least one duct. The temperature of the first process gases may be controlled by controlling a temperature and/or flow rate of the coolant or heating agent passed through the at least one duct.

The system may further comprise a heat insulator or heat shield interposed between the plurality of projections and at least a portion of the second flow path.

The second flow path may comprises a plurality of channels disposed radially outward of the plurality of projections. The plurality of channels of the second flow path may be distributed evenly in a circumferential direction around the outer circumference of the first flow path.

The second temperature adjustment mechanism may comprise a heater having orifices arranged to allow process gases from both the first flow path and the second flow path to pass through the orifices to the substrate.

The system may be configured to pass a first group of process gases through the first flow path at a first flow velocity and to pass a second group of process gases through the second flow path at a second flow velocity which is less than the first flow velocity. The second group of process gases may be different from the first group of process gases. The system may comprise a valve or another control mechanism for controlling flow rates, to thereby set the flow velocity in the second flow path to be less than the flow velocity in the first flow path. The flow velocity may respectively be defined as the length of travel through the first or second flow path, respectively, divided by the time of travel through the first or second flow path, respectively.

The second and third temperature adjustment mechanism may respectively comprise a heater which has a low thermal mass. The heaters of the second and third temperature adjustment mechanism may be heated up and cooled down by at least up to 100° C. within seconds.

The substrate may have a first surface and a second surface opposite to the first surface. The first surface may be a first major surface of the substrate, and the second surface may be a second major surface of the substrate. The second and third temperature adjustment mechanisms may form a heater which is located at a distance from the substrate and configured to apply heat to the substrate from the side of the first surface and from the side of the second surface of the substrate.

The heater may be configured to apply heat of a first temperature to the first surface and a second temperature to the second surface of the substrate.

The heater may be a three-dimensional heater.

The second temperature adjustment mechanism may comprise a heating unit located at a first distance to the first surface of the substrate and the third temperature adjustment mechanism may comprise a heating unit located at a second distance to the second surface of the substrate. The heater may be arranged asymmetrically with respect to the first and second surface of the substrate, i.e., the first and second distances may be different from each other.

The heater may be one of a resistive heater, an RF heater and an electromagnetic heater. The heater may be configured to apply a profiled heat distribution to the substrate and/or configured to apply heat dynamically.

The system may comprise a holding member for holding the substrate. The holding member may touch at least one surface of the substrate. The holding member may be positioned at the first and/or the second surface of the substrate or at a third and/or fourth surface of the substrate.

The holding member may be positioned at a center region of one of the surfaces of the substrate or an edge region of one of the surfaces of the substrate.

The system is configured to cause rotation and levitation of the substrate during deposition and/or etching of the substrate. The system may comprise a carrier located below the substrate. The heating member may act as the carrier. The carrier may comprise at least two gas conduits to provide gas to the substrate's bottom surface to levitate the substrate above the carrier. The system may comprise at least one holding member connected to the carrier and configured to restrict drifting of the substrate.

The substrate bottom heater may be the carrier in which the gas conduits are formed for levitating and rotating the substrate using a gas flow.

At least three gas conduits may be provided in the substrate bottom heater or other carrier. The at least three gas conduits may be inclined such that gas passing through the at least three gas conduits provides a rotational force to the substrate.

The gas conduits may have a direction which may vary, e.g., along an axis of the gas conduits. The gas conduits may thereby be provided with a helical configuration. The inclined gas conduits may lie within a plane which is parallel to a tangential plane to the substrate's edge to provide a rotational force to the substrate.

The inclined gas conduits may lie within a plane defined by (i) a first vector which is normal to the substrate's radius or the carrier's radius and (ii) a second vector which lies within the bottom plane of the substrate or carrier and which is perpendicular to the substrate's radius or the carrier's radius at the position of the inclined gas conduit. The inclined gas conduits may be inclined with respect to a vector which is normal to the radius vector of the substrate or carrier and which lies within a plane of the bottom surface of the substrate or carrier.

An inclination angle of the inclined gas conduits, measured as angle between a center line of the gas conduit and the vector normal to the bottom surface of the substrate, may be between 2° and 60°, preferably between 5° and 50°, more preferably between 10° and 45°. In some embodiments, the inclination angle may be between 25° and 35°. In some embodiments, the inclination angle may be between 28° and 32°. The inclination angle of the gas conduits may be about 30°.

The gas applied through the gas conduits to the bottom surface of the substrate may reduce the risk that process gases applied to the top surface of the substrate pass to the bottom surface of the substrate and produce parasitic coating or etching on the bottom surface of the substrate.

In addition, due to the flow over rotating disc effect, the rotating substrate can attract the process gas closer to the substrate and thereby improve the efficiency of the deposition or etching process.

A distance between each of the at least three gas conduits and a center of the substrate bottom heater or carrier may be greater than 30% of a radius of the substrate, preferably greater than 50% of the radius of the substrate, more preferably greater than 70% of the radius of the substrate.

A distance between each of the at least three gas conduits and a center of the substrate bottom heater or carrier may be greater than 22.5 mm, preferably greater than 37.5 mm, more preferably greater than 52.5 mm as example for a 6″ wafer.

The system may be adapted to rotate the substrate with a rotational velocity between 60 rpm and 2000 rpm.

The system may be adapted to control the gas flow through the at least three gas conduits to control the rotational velocity of the substrate.

The at least one holding member may comprise a single holding member located at the carrier such that the holding member receives the substrate at a central position thereof.

The at least one holding member may comprises at least three holding members located at the carrier such that the three holding members receive the substrate at an edge region thereof.

The at least one holding member may have an increasing diameter towards the carrier.

The upper surface of the carrier facing the substrate may be substantially flat.

The at least two gas conduits may be formed as a hole or a hollow pin through the carrier.

The at least two gas conduits may be located at an outer area of the substrate.

The at least one holding member may further comprise a rotational speed sensor and/or a positional sensor to measure the rotation and/or the position of the substrate.

The upper surface of the carrier, which may be formed by a substrate bottom heater, may be substantially flat. The upper surface of the carrier may have a surface flatness of at most 0.1 mm. The upper surface of the carrier may have a surface flatness of at most 0.1 mm when determined using optical measurement techniques, such as optical measurement devices commercially available from k-Space Associates, Inc., Dexter, Mich., USA. The upper surface of the carrier may have a surface flatness of at most 0.1 mm when determined in accordance with DIN ISO 2768. In the absence of significant recesses in the upper surface of the carrier, undesired temperature variations along the surface of the substrate are reduced. Such undesired, uncontrollable temperature variations would normally be prone to arise when larger recesses need to be provided in the substrate bottom heater or another carrier.

A gas phase deposition method according to a preferred embodiment comprises passing a first group of process gases through a first flow path of a gas injector to a substrate. The method comprises passing a second group of process gases through a second flow path of the gas injector, the second flow path being different from the first flow path and the second group of process gases being different from the first process gases. The method comprises controlling a first temperature adjustment mechanism associated with the first flow path to control a temperature of the first process gases passing through the first flow path. The method comprises controlling a second temperature adjustment mechanism associated with at least the second flow path to control a temperature of the second group of process gases passing through the second flow path, the first temperature adjustment mechanism and the second temperature adjustment mechanism being operable independently of each other. The substrate may be levitated and rotated during deposition and/or etching

The method may be performed using the system described above. Additional features which may be implemented in the method according to preferred embodiments and the effects respectively attained thereby correspond to the features and effects described in the context of the gas phase deposition system according to preferred embodiments.

The method may comprise controlling a third temperature adjustment mechanism to heat or cool at least one surface of the substrate.

The third temperature adjustment mechanism may be operated independently of the first temperature adjustment mechanism and the second temperature adjustment mechanism. Further improved process control is attained thereby.

The method may comprise heating the substrate from a first surface using the second temperature adjustment mechanism and heating or cooling the substrate from a second surface using the third temperature adjustment mechanism, the second surface being opposite the first surface.

In the method, the second and third temperature adjustment mechanisms may respectively be arranged so as to be spaced from the substrate.

The method may comprise controlling, by a control unit, at least one of the first, second and third temperature adjustment mechanisms as a function of time in a manner coordinated with a time-dependent variation of a flow of the first group of process gases through the first flow path. Thereby, a spike deposition may be implemented in which higher layer quality may be attained at average lower substrate temperature.

The control unit may be configured to control the temperature of a substrate bottom heater of the third temperature adjustment mechanism as a function of time in a manner coordinated with the time-dependent variation of the flow of the first group of process gases through the first flow path.

The first flow path may comprise a plurality of projections respectively extending along a longitudinal axis. Each one of the plurality of projections may respectively have an internal cavity extending along the longitudinal axis. The method may comprise passing the first group of process gases through the respective projection and through an outlet opening of the projection. The projections may respectively be hollow pins or other hollow gas outlets.

The first flow path may further comprise a member having at least one internal cavity in communication with the cavities of the plurality of projections. The plurality of projections may project from a major face of the member and may be thermally coupled to the member. The member may be a hollow plate which may have a shape and size that is matched to, and which may be equal to, the shape and size of the substrate. The method may comprise passing a coolant or heating agent through the member to thereby heat or cool the first group of process gases.

The gas outlets may be arranged to have their output openings positioned at orifices formed in a heater of the second temperature adjustment mechanism. Each one of the gas outlets may be associated with a corresponding orifice in the heater. The method may comprise passing the first group of process gases through the gas outlets, thereby maintaining the first group of process gases at a temperature lower than a threshold temperature, which may be less, in particular much less, than a temperature of the heater, before passing the first group of process gases to the substrate through the orifices of the heater.

A source of electromagnetic radiation, in particular a light source, may be comprised by or coupled to at least a subset of the gas outlets. The method may comprise controlling, by the control unit, the source of electromagnetic radiation comprised by or attached to gas outlets to activate ad-atoms movement to promote higher quality growth at lower substrate temperature. The method may comprise controlling, by the control unit, the source of electromagnetic radiation comprised by or attached to the gas outlets to measure substrate temperature remotely, e.g., by utilizing black (gray) body radiation effect or by using other physical effects like Raman scattering etc. By utilizing the active light source going through the same path the growth and/or etch rate of the layer can be established in situ.

The method may comprise passing a first group of process gases through the heater of the second temperature adjustment mechanism, while preventing the first group of process gases from being significantly heated by the heater of the second temperature adjustment mechanism.

The first flow path may comprise at least one duct for a coolant or heating agent. The method may comprise controlling a temperature of the first group of process gases by controlling a temperature and/or flow rate of the coolant or heating agent passed through the at least one duct.

In the method, the first group of process gases may be passed through the first flow path at a first flow velocity and the second group of process gases may be passed through the second flow path at a second flow velocity which is less than the first flow velocity. The second group of process gases may be different from the first group of process gases. The flow velocity may respectively be defined as the length of travel through the first or second flow path, respectively, divided by the time of travel through the first or second flow path.

Various effects may be attained using the systems and methods according to preferred embodiments. The system and method allow three temperatures to be controlled essentially independently within one process chamber. Each temperature can be changed within its process window during a process cycle many times, so as to independently provide good or even optimum conditions for deposition of the desired material. Low thermal mass heaters may be utilized to allow the process parameters to be changed rapidly.

The enhanced control over the gas phase deposition process allows various effects to be attained. For illustration, if a lower substrate temperature is required to achieve good adhesion or to avoid substrate degradation, the second flow path may still provide a sufficient amount of process gas, which may include a precursor, to the substrate surface to attain good deposition and to provide the energy required for performing chemical reactions on the surface. This similarly applies when lower substrate temperature is required to prevent instability of the grown layer. Because substrate temperature and at least the temperature of the first reactant and precursor gas may be set independently of each other, the system and method according to the disclosure obviate the need to significantly increase the amount of precursor even when the substrate is kept at a lower temperature. Thereby, gas phase reactions may be reduced, which provides benefits in terms of precursor consumption and costs. Further, the quality of the depositing layer may be improved and process chamber efficiency may be enhanced, thereby reducing the frequency of maintenance work, size and costs of the facility equipment.

The system and method may also be operative to simultaneously deposit material from both the first flow path and the second flow path. This can be done in an efficient way, and turbulences may be eliminated or reduced. Because the enhanced temperature control allows the flow of a component to be reduced compared to conventional systems and methods, the carrier gas flow in at least one of the first and second flow paths may be reduced. This facilitates establishing flow balance.

In the systems and method according to embodiments, the gas injector may be used in combination with a hot wall reactor without being limited thereto. The gas injector allows vertical flows of process gases to be used in a hot wall reactor, without being limited thereto.

In the systems and method according to embodiments, the gas injector may be used in combination with a cold wall reactor or in combination with a reactor that is switchable between hot wall reactor operation and cold wall reactor operation. The gas injector may also be used in combination with reactors other than hot wall reactors and cold wall reactors.

The systems and methods according to preferred embodiments are also suited for growing special layers on sensitive substrates which cannot withstand elevated temperatures for long periods. To this end, the temperature of a substrate heater may be varied in a pulsed fashion, coordinated with a pulsed supply of first group of process gases through the first flow path.

Similar techniques may be used to enable a gas phase deposition process at low temperature, where only during short pulses the temperature will exceed a temperature threshold. The second flow path may in this case still provide a sufficient amount of activated process gas to the surface.

The systems and methods according to preferred embodiments may be operative to perform Metalorganic Vapour Phase Epitaxy (MOVPE) or Metalorganic Chemical Vapour Deposition (MOCVD), without being limited thereto.

Preferred embodiments will now be described with reference to the drawings. While various specific details are shown in the drawings and will be set forth below, it is to be understood that modifications and alterations may be implemented in other embodiments.

### BRIEF DESCRIPTION OF THE DRAWINGS

FIG. 1 is a schematic view of a gas phase deposition system according to a preferred embodiment.

FIG. 2 is a sectional view of a gas phase deposition system according to a preferred embodiment.

FIG. 3 is a perspective view of a first flow path of a gas phase deposition system according to a preferred embodiment.

FIG. 4 is a diagram illustrating temperature profiles in the gas phase deposition system of FIG. 2.

FIG. 5 is a schematic view of a gas phase deposition system according to a preferred embodiment.

FIG. 6 is a sectional view of a gas phase deposition system according to a preferred embodiment.

FIG. 7 is a schematic view illustrating an arrangement of gas conduits for substrate levitation and/or rotation which may be used in the gas phase deposition system of FIG. 6.

FIG. 8 is a diagram illustrating a process control which may be implemented in a gas phase deposition method according to a preferred embodiment.

FIG. 9 is a partial cross-sectional view of a gas outlet of the first flow path according to a preferred embodiment.

FIG. 10 is a sectional view of a gas phase deposition system according to a preferred embodiment.

FIG. 11 is a partial top view of a gas phase deposition system according to a preferred embodiment.

FIG. 12 is a schematic view illustrating an arrangement of gas conduits for substrate levitation and rotation which may be used in the gas phase deposition system of FIG. 6, FIG. 10, and FIG. 11.

FIG. 13 illustrates a lost area versus the exclusion width in conventional systems and in exemplary embodiments of the present disclosure.

### DETAILED DESCRIPTION OF THE PREFERRED EMBODIMENT

Preferred embodiments of the disclosure will be described with reference to the drawings in which identical or similar reference numerals designate identical or similar elements. The features of the various embodiments may be combined with each other unless explicitly stated otherwise. While some embodiments are described in the context of Metalorganic Vapour Phase Epitaxy (MOVPE) or Metalorganic Chemical Vapour Deposition (MOCVD), the gas phase deposition systems and gas phase deposition methods according to embodiments are not limited thereto.

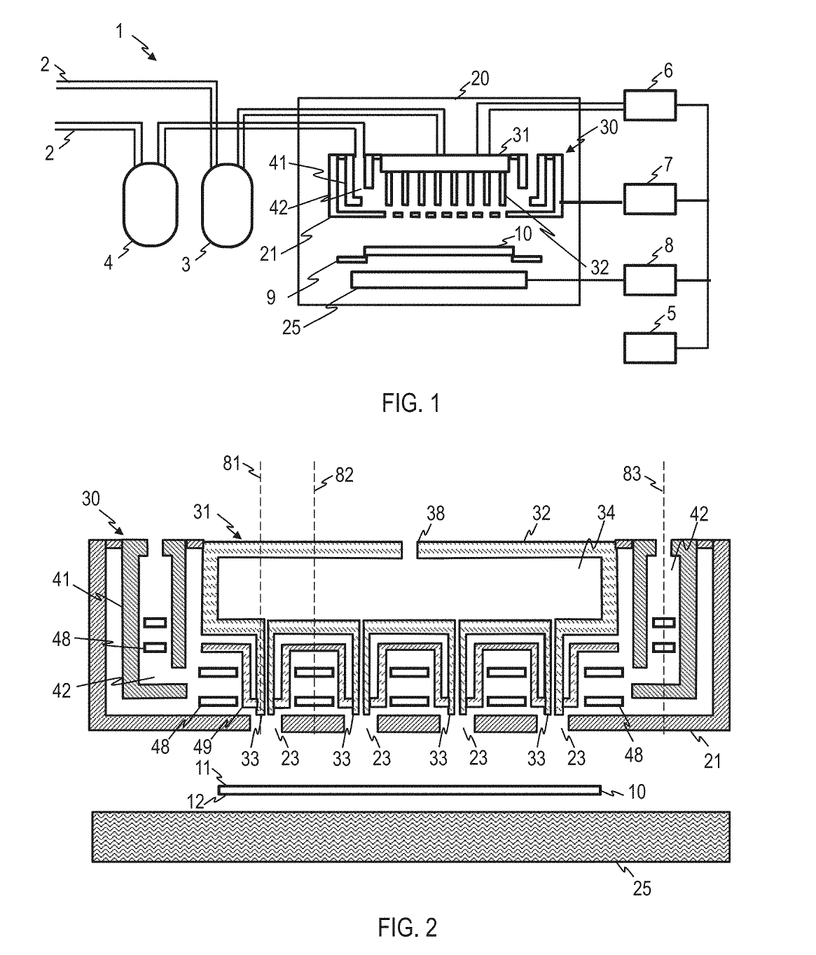

FIG. 1 shows a system 1 for gas phase deposition according to a preferred embodiment. FIG. 2 shows an enlarged partial cross-sectional view of the gas injector and other components of the system 1.

The system 1 is operative to deposit one or several different materials onto a substrate 10 in a process chamber 20. The process chamber 20 may be a reactor. As will be explained in more detail below, the system 1 is configured in such a manner that a first group of process gases may be passed through a first flow path 31 of a gas injector 30 and that a second group of process gases may be passed through a second flow path 41 of the gas injector 30. The first flow path 31 and the second flow path 41 may be arranged to face the same surface 11 of the substrate 10, which may be one of the major surfaces of the substrate.

The system 1 is configured such that a first temperature adjustment mechanism 6 and a second temperature adjustment mechanism 7 are independently adjustable, to thereby set temperatures for the first group of process gases and for the second group of process gases to different values. This may be achieved in various ways. For illustration, the first flow path may be cooled by a coolant circulated by a coolant source and may have a plurality of projections to respectively guide the first group of process gases to orifices 23 in a heater 21. The temperature of the first group of process gases upon passage out of the first flow path may be controlled by the coolant circulation. A different temperature may be set for a second group of process gases which is passed through channels 42 of a second flow path 41.

The system 1 may comprise a first bubbler 3 which may be connected to the process chamber 20 so as to supply a first group of process gases to the first flow path 31 of the gas injector 30. The system 1 may comprise a second bubbler 4 which may be connected to the process chamber 20 so as to supply a second group of process gases to the second flow path 41 of the gas injector 30. Ducts 2 may provide process gases to the process chamber 20. The first and second group of process gases may be different from each other. Sources of reactants or precursors different from bubblers may be used. For illustration, gas sources, vaporizers, vapour sources, or other sources of reactants or precursors may be used.

As used herein, the term “process gas” is used to refer to gas which includes at least one of a reactant, a precursor, a carrier gas, or mixtures thereof The terms “a process gas” or a group of process gas” may be used to refer to carrier gas in which reactants or precursors may be entrained, for example. A process gas may be entrained in the same carrier gas or in two or more different carrier gases. The term “group of reactants” is used to refer to the sources for physicochemical reactions with a purpose to grow different kind of layers or to etch grown layers or substrate itself. Reactants in most cases are in gaseous state, but not limited thereto. Reactants can consist 100% of substance or may be diluted to a certain extent with a gas not taking part in physicochemical reactions. The reasons for substance dilution can be different. Such reasons may include, without limitation, safety, necessity to supply only a small amount of substance in case of doping purpose to the requirements to achieve the total flow balance (to avoid turbulences or back flow regime) and to grow or etch uniform layers from the thickness and composition point of view in cross-flow or, as they are also called in a different way, horizontal flow reactors. In the two latter cases such a dilution gas is called carrier gas and has the role of bringing the group of reactants to a certain distance within the reactor area or to compensate the flow of another group of reactants to avoid turbulences or even clogging, which might work as gas-based valve preventing the certain group of reactants to reach the substrate surface.

The carrier gas, if present, may include one or several of H₂, N₂, elements of group VII, or other appropriate gases.

The system 1 may comprise a control unit 5. The control unit 5 may comprise one or several integrated circuits, such as processors, microprocessors, application specific integrated circuits, controllers, microcontrollers, or combinations thereof that are configured to control operation of at least some components of the system 1. The system may comprise valves or other flow control components (not shown) that control the flow of the first group of process gases and of the second group of process gases to the gas injector 30. The control unit 5 may be configured to control the valves or other flow control components to set the flow of the first group of process gases and of the second group of process gases. For illustration, the control unit 5 may be configured to adjust the flow rates of the first group of process gases and of the second group of process gases in such a manner that a first flow velocity of the first group of process gases through the first flow path 31 exceeds a second flow velocity of the second group of process gases through the second flow path 41.

The system 1 may comprise a first temperature adjustment mechanism 6 which is associated with the first flow path 31 of the gas injector 30. The first temperature adjustment mechanism 6 may comprise a coolant source or a heating agent source. The first temperature adjustment mechanism 6 may be configured to circulate the coolant or the heating agent through at least a portion of the first flow path 31 to thereby control a temperature of the first group of process gases output by the first flow path 31 towards the substrate 10. The control unit 5 may be configured to control operation of the first temperature adjustment mechanism 6. The control unit 5 may be configured to control operation of the first temperature adjustment mechanism 6 in a time-dependent manner, e.g., during a process cycle. The control unit 5 may in particular be configured to control operation of the first temperature adjustment mechanism 6 so as to ensure that the temperature of the reactant(s) or precursor entrained in the carrier gas of the first group of process gases is set to attain optimum or close to optimum deposition for the respective material(s).

The system 1 may comprise a second temperature adjustment mechanism 7 which is associated with the second flow path 41 of the gas injector 30. The second temperature adjustment mechanism 7 may comprise a heater, e.g., a resistive heater or an inductive heater, or a source of electromagnetic radiation, e.g., a laser source, operative to control a temperature of the second group of process gases output by the second flow path 41 towards the substrate 10. The second temperature adjustment mechanism 7 may adjust a temperature of a heater 21. The heater 21 may comprise a top heater plate that faces a top surface 11 of the substrate 10. The heater 21 and the second flow path 41 may be configured such that heat is transferred from the heater 21 to the second flow path 41, such as by thermal conduction, by thermal radiation, or in other ways. The control unit 5 may be configured to control operation of the second temperature adjustment mechanism 7. The control unit 5 may be configured to control operation of the second temperature adjustment mechanism 7 in a time-dependent manner, e.g., during a process cycle. The control unit 5 may in particular be configured to control operation of the second temperature adjustment mechanism 7 so as to ensure that the temperature of the reactant(s) or precursor entrained in the carrier gas of the second group of process gases is set to attain optimum or close to optimum deposition for the respective material(s).

The system 1 may comprise a third temperature adjustment mechanism 8 which may include a substrate bottom heater 25. The third temperature adjustment mechanism 8 may comprise a resistive heater or an inductive heater, or a source of electromagnetic radiation operative to control a temperature of the substrate 10 from at least one substrate surface 12. The control unit 5 may be configured to control operation of the third temperature adjustment mechanism 8. The control unit 5 may be configured to control operation of the third temperature adjustment mechanism 8 in a time-dependent manner, e.g., during a process cycle. The control unit 5 may in particular be configured to control operation of the third temperature adjustment mechanism 8 so as to ensure stability of the grown layers and of the substrate 10, for example. The system 1 may comprise a laser for a measurement of a growth rate or etch rate of a transparent layer. The system 1 may be configured to measure the growth rate or etch rate of a transparent layer based on measuring oscillations of reflectance of a laser beam generated by the laser source.

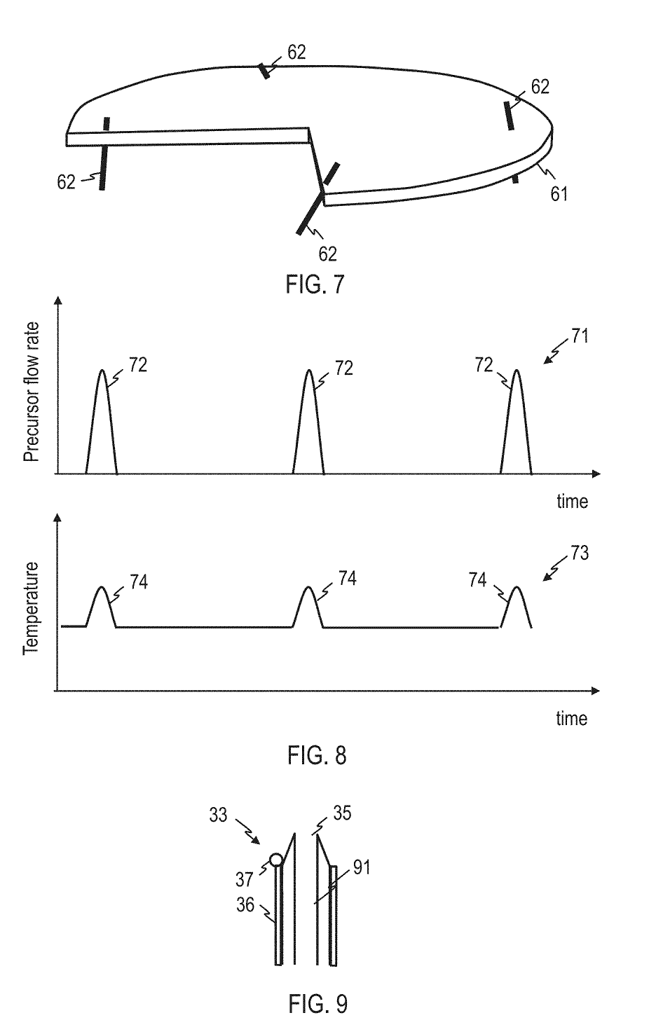

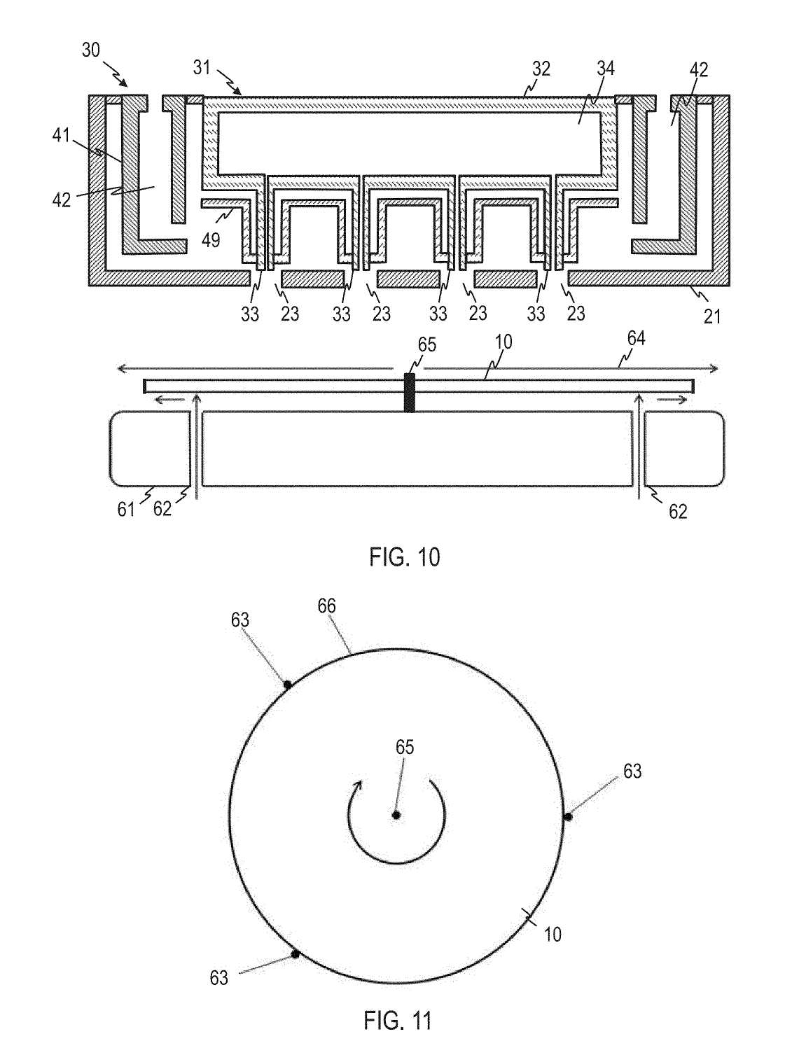

The substrate 10 may be held in the process chamber 20 by a holder. The holder may comprise holding elements 9 that hold the substrate 10 in a spaced relationship from the heater 21 that faces the first surface 11 of the substrate 10 and the substrate bottom heater 25 that faces the opposing second surface 12 of the substrate 10. As will be explained in more detail with reference to FIG. 6, FIG. 7, and FIG. 10 to FIG. 13, the system 1 may comprise a holding mechanism operative to levitate and rotate the substrate 10.

The system 1 may be configured in such a way that no heat-absorbing elements and, preferably, no elements at all are arranged in between the heater 21 and the substrate 10 held by the holder and/or that no heat-absorbing elements and, preferably, no elements at all are arranged in between the substrate bottom heater 25 and the substrate 10.

The substrate 10 includes at least one surface 11 where growth or etching processes take place. Initially, the substrate may be a single bulk material made of compound base material (like GaAs) or elementary based material (like Si). During the deposition process, the substrate 10 can be covered with a layer of a different material. The newly grown layer may have different characteristics and may define the surface characteristics and therefore the substrate characteristics at least at the surface. This type of substrate can be called composite or template material, to distinguish it from single bulk material mentioned above.

During operation, the control unit 5 may control the first temperature adjustment mechanism 6, the second temperature adjustment mechanism 7 and, optionally, the third temperature adjustment mechanism 8 and the flow of the first and second groups of process gases. The first flow path 31 may be kept at a temperature which is less than a temperature of the second flow path 41. The temperatures of the first and second flow paths may respectively be defined as averages over the respective flow path. The first flow path 31 may therefore act as a “cold path” for supplying a process gas to the substrate 10 and the second flow path 41 may act as a “hot path” for supplying a further process gas to the substrate 10. Further, when the system 1 comprises the second temperature adjustment mechanism 7 to adjust a temperature of a heater 21 and the third temperature adjustment mechanism 8 to independently adjust the temperature of the substrate bottom heater 25, the temperatures in the spaces above and below the substrate 10 may respectively be controlled independently of each other.

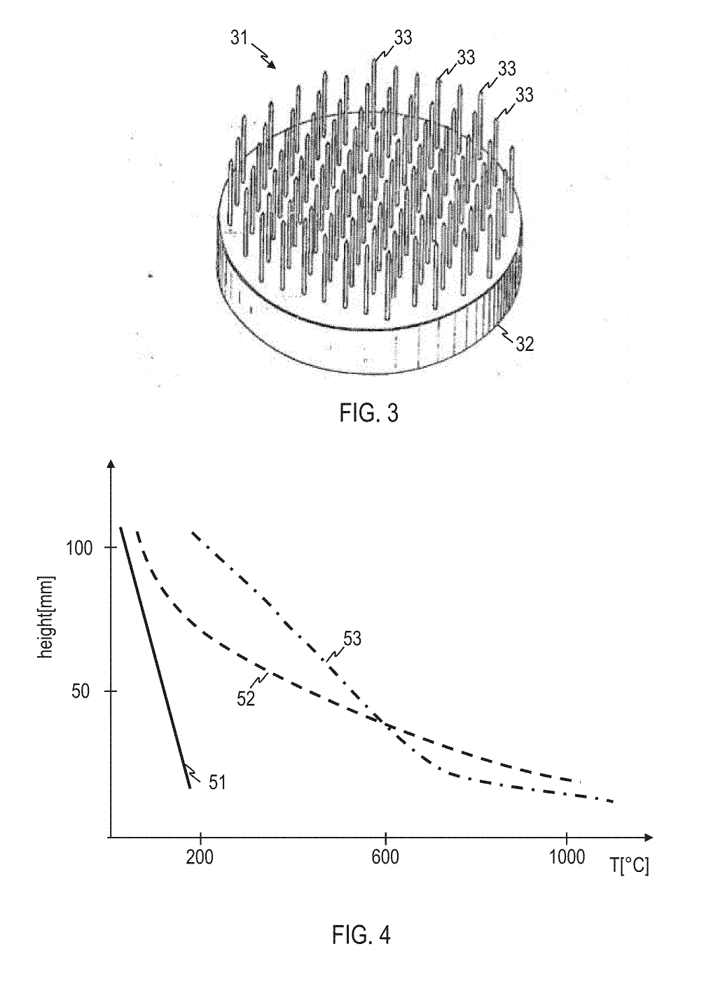

A gas injector 30 of a gas injection system according to a preferred embodiment will be described in more detail with reference to FIG. 2 and FIG. 3 which shows a perspective view of a first flow path 31 according to a preferred embodiment. The gas injector 30 generally comprises the first flow path 31 and the second flow path 41. The first and second flow paths 31, 41 may be attached to each other or may be integrally formed in such a manner that the first flow path 31 and the second flow path 41 are respectively configured to output process gases towards the substrate 10 through common orifices 23, which may be formed in the heater 21. The first and second flow paths 31, 41 may be arranged to face the same surface 11 of the substrate 10.

The first flow path 31 may comprise a member 32 which may be cooled by water or another coolant. The member 32 may be a hollow plate. The member 32 may have a cylindrical shape or a different shape, which corresponds to the shape of the substrate 10. The member 32 has an internal cavity 34. The member 32 has an inlet opening 38 through which a first group of reactant gases or precursors may be supplied to the first flow path.

Gas outlets 33, which may be hollow pins, respectively have an internal cavity extending along a longitudinal axis of the gas outlets 33, to thereby guide the process gases towards the process area of the substrate 10. The length of the gas outlets 33 may vary from 10 mm to 100 mm, without being limited to this range. The length of the gas outlets may depend on the maximum temperature of the heater 21.

The gas outlets 33 may be integral with the member 32. Alternatively, the gas outlets 33 may be coupled to the member 32 so as to ensure heat transfer by heat conduction between the member 32 and the gas outlets 33.

An inner diameter of the gas outlets 33 may vary from 0.1 mm to 1 mm, without being limited to this range. The inner diameter of the gas outlets 33 may be set so as to provide a gas velocity which is sufficiently large to avoid precursor decomposition during passing through the gas outlet in high temperature environment.

The density of the gas outlets 33 on the major face of the member 32 may vary between 0.1 cm⁻² and 20 cm⁻², without being limited to this range. The gas outlets 33 may be arranged in concentric circles on the member 32. The gas outlets 33 may be also arranged in rectangular order, e.g., a square order. The hollow gas outlets 33 can be interlaced, e.g., in a checkerboard pattern or in a similar way, with two or more types of hollow gas outlets to introduce two or more types of precursors, which should not be mixed together before reaching the substrate area. Other arrangements may be used. The arrangement of gas outlets 33 may match the arrangement of orifices 23 in the heater 21. In particular, when projected onto a plane in which the substrate top surface 11 extends, the centers of the outlet openings of the gas outlets 33 may have an arrangement that may substantially correspond to, or may be identical to, the arrangement of the centers of the orifices 23. At least some of the gas outlets 33, and preferably each one of the gas outlets 33, may be arranged concentrically with a corresponding orifice 23 in the heater 21.

The gas outlets 33 and/or the orifices 23 may be arranged in a regular pattern. The gas outlets 33 and/or the orifices 23 may be arranged in a rectangular pattern, in particular a square pattern.

The gas outlets 33 and/or the orifices 23 may be arranged in a plurality of circles, in particular in a plurality of concentric circles. A circular pattern may be particularly suitable for, e.g., circular substrates.

The gas injector 30 may be configured in such a manner that heat transfer between the first and second flow paths and/or other undesired processes may be reduced. An inner gas outlet surface may be polished to reduce the adsorption and desorption processes. The outer surface of the gas outlets 33 may be polished for better reflection of thermal radiation. Alternatively or additionally, the outer surface of the gas outlets 33 may be provided with a high reflective coating of metals such as Au (gold) or Al (aluminum) for example, without being limited thereto. Each gas outlet 33 may be provided with a heat jacket in a form of ceramic bushing or sleeve, which at least partially surrounds the gas outlet 33 for better thermal protection from hot environment. The gas outlets 33 may respectively reach the surface of the heater 21 and may be arranged such that they are located in front of corresponding orifices 23, which may be holes made in the heater 21. Thereby, the first group of process gases, i.e., the mixture of the carrier gas and precursor, can reach the process area and the substrate at lower temperature than the second group of process gases. The temperature of the first group of process gases can be adjusted by changing the temperature and/or flow rate of the cooling water, and/or the temperature of any other coolant or heating agent. To prevent overheating at high temperature processes, one or several heat shields 49 may be interposed between at least a portion of the first flow path 31 and the second flow path 41. The one or several heat shields 49 may have a shape that follows the outer shape of the first flow path 31.

The second flow path 41 may be arranged to achieve high preheating for the second group of process gases in a circumferential area. The second flow path 41 may comprise a plurality of channels 42 that are arranged around the first flow path 31. For illustration, the channels 42 of the second flow path 41 may be evenly distributed around the cylindrical element that defines the first flow path 31.

When compared to the movement of the first group of process gases at a first velocity through the first flow path 31, the flow velocity through the second flow path 41 is slower. The second group of process gases may be passed through the second flow path 41 at a second velocity which is less than, and which may be much less than, the first velocity at which the first group of process gases is passed through the first flow path 31. The second flow path 41, i.e., the “hot path” 41, presumes a flow velocity which is sufficiently slow, such that after multiple interactions between reactant mixture with a carrier gas and the heater surface the reactant(s) or precursor in the second group of process gases have a temperature that approaches that of the heater 21.

The second flow path 41 may output the reactant component passing through the orifices 23 in the heater 21, through which the reactants passing through the first flow path 31 are also output to the substrate 10. The process gases entrained in the first group and in the second group, respectively, are mixed just in front of the surface 11 of the substrate 10.

The substrate 10, in particular the outer surface(s) 11, 12 of the substrate 10, may additionally be heated by the bottom heater 25 of the third temperature adjustment mechanism. The bottom heater 25 may have a configuration as described in European Patent Application No. 15 20 2296.8.

The system 1 allows three temperatures to be controlled essentially independently within one process chamber 20, i.e., the temperature of the process gases passing through the first flow path 31, the temperature of the process gases passing through the second flow path 32, and the substrate temperature. Each temperature can be changed within its process window during the process cycle. Such changes in temperature may occur independently many times, so as to provide good or even optimum conditions for deposition of desired material. Low thermal mass heaters may be utilized which can be heated up and cooled down by up to ˜100° (hundreds) of degrees Celsius within seconds. Alternatively or additionally, other types of lower performance heaters can be utilized if desired in the interest of cost-efficiency. Further enhanced process control may be implemented by using the gas outlets 33 for illuminating the substrate area with a light source capable of activating ad-atoms movement.

The orifices 23 may have a center axis which passes through the heater 21 in a direction normal to a major face of the substrate, i.e., parallel to a normal of the substrate surface. Alternatively or additionally, the longitudinal axes of the gas outlets 33 may extend in a direction normal to a major face of the substrate, i.e., parallel to a normal of the substrate surface.

The orifices 23 may have a center axis which is inclined relative to a normal direction of the substrate. Alternatively or additionally, the longitudinal axes of the gas outlets 33 may be inclined relative to the normal direction of the substrate. The orifices 23 and/or gas outlets 33 may be inclined to thereby attain a laminar flow at the substrate surface and/or a uniform distribution of gas at the substrate. The utilization of the process media may be enhanced thereby. The center axes of at least a fraction of the orifices 23 and/or of at least a fraction of the gas outlets 33 may be inclined relative to the major face of the member 32.

At least one gas diffuser or shield 48 may be arranged in the channel 42 of the second flow path 41. At least one gas diffuser or shield 48 may be arranged upstream of a surface of the heater 21. The at least one gas diffuser or shield 48 may prolong the dwell time of the second group of process gases in the channel 42 of the second flow path 41. The gas diffuser or shield 48 may enhance heating efficiency and/or may facilitate flow direction control for the second group of process gases.

The gas injector 30 may be used in a hot wall reactor or in a cold wall reactor. The gas injector 30 may be used in combination with a reactor that is controllable to selectively perform cold wall reactor operation or hot wall reactor operation. The control unit 5 may be operative to control the reactor to operate time-sequentially as a hot wall reactor and as a cold wall reactor.

FIG. 4 is a diagram illustrating the temperature variation along various lines perpendicular to the substrate top surface 11 within the gas injector 30. The temperature is respectively shown as a function of height above the surface of the heater 21 facing the substrate, which is located at a height of 0 mm. A temperature 51 is measured along an axis of the gas outlet 33, indicated by line 81 in FIG. 2. The temperature 51 remains much lower than the temperature of the heater 21, even as the gas in the gas outlet approaches the heater 21. The temperature 51 varies only weakly as a function of position, ensuring that the first group of process gases is supplied at a temperature which is less than, and which may be much less than, the temperature of the heater 21 through which it is passed. A temperature 52 is measured along an axis, indicated as axis 82 in FIG. 2, parallel to the longitudinal axes of the gas outlets 33, but located at a center in between adjacent gas outlets 33. The temperature 52 approaches the temperature of the heater 21 at positions approaching the heater 21. As can be taken by a comparison of the temperature profiles 51, 52, the temperature 51 at the gas outlets remains much lower than the temperature 52 outside of the gas outlets. A temperature 53 is measured along a peripheral region of the heater 21, as indicated as line 83 in FIG. 2. As can be taken by a comparison of the temperature profiles 51, 53, the temperature 51 within the gas outlets remains much lower than the temperature 53 at the peripheral region of the heater where the second flow path may be arranged. The gas injector 30 is operative to provide first and second group of process gases to the substrate at significantly different temperatures.

It will be appreciated that the capability of controlling two or three temperatures within one process chamber 20 significantly enhanced process control. For illustration, in terms of synthesis of a compound AB from components A and B on the substrate 10, there are generally four temperatures T_{A}, T_{B}, T_{AB} and T_{S}, where T_{A} designates the temperature that would be optimum for component A, T_{B} designates the temperature that would be optimum for component B, T_{AB} designates the temperature that would be optimum for compound AB, and T_{S} designates the temperature that would be optimum for the substrate. T_{AB} and T_{S} may be identical, e.g., when growing a bulk layer of the same material like the substrate itself, or very similar, such that there are three generally independent and different temperatures. The enhanced control provided by the system and method according to embodiments allows the different optimum temperatures T_{A}, T_{B}, and T_{AB}=T_{S} to be taken into account by independently controlling the temperature adjustment mechanisms 6, 7, 8.

The control unit 5 may control the temperature adjustment mechanisms 6, 7, 8 and/or the gas flow in various ways, depending on the characteristics of the substrate and of the growing layer(s).

The control unit 5 may control temperature adjustment mechanisms in such a way that the reactant components going through the second flow path 41 can provide a sufficient amount of activated precursor to the substrate surface even if the substrate temperature must be kept below a threshold temperature to achieve good adhesion or to avoid substrate degradation still. The control unit 5 may control temperature adjustment mechanisms in such a way that the reactant components going through the second flow path 41 can supply activated precursor for more efficient deposition even if a lower substrate temperature is required, because of instability of the grown layer at high temperature.

The control unit 5 may control the substrate temperature and the inlet gas temperature independently of each other, so as to reduce gas phase reactions. The shortcomings associated with introducing an excessive amount of precursor, which would give rise to the gas phase reaction processes, and the costs associated with high precursor consumption are mitigated. Reduction or elimination of gas phase reactions improves the quality of depositing layer and improves process chamber efficiency, thus reducing the frequency of maintenance and size and costs of facility equipment.

The control unit 5 may control the supply of at least one group of process gases through both the first flow path 31 and the second flow path 41 for simultaneous deposition from two inlet paths 31, 41 in such a way that a total flow balance is attained to bring both components to the surface in an efficient way and eliminate turbulences. Establishing the flow balance and reducing turbulence is facilitated by the fact that the enhanced control over process parameters obviates the need of introducing excessive amounts of precursor, thereby facilitating flow balance.

The control unit 5 may also control the supply of at least one group of process gases and/or the temperatures established by the temperature adjustment mechanisms 6, 7, 8 in a time-dependent manner, as will be explained in more detail with reference to FIG. 8 below.

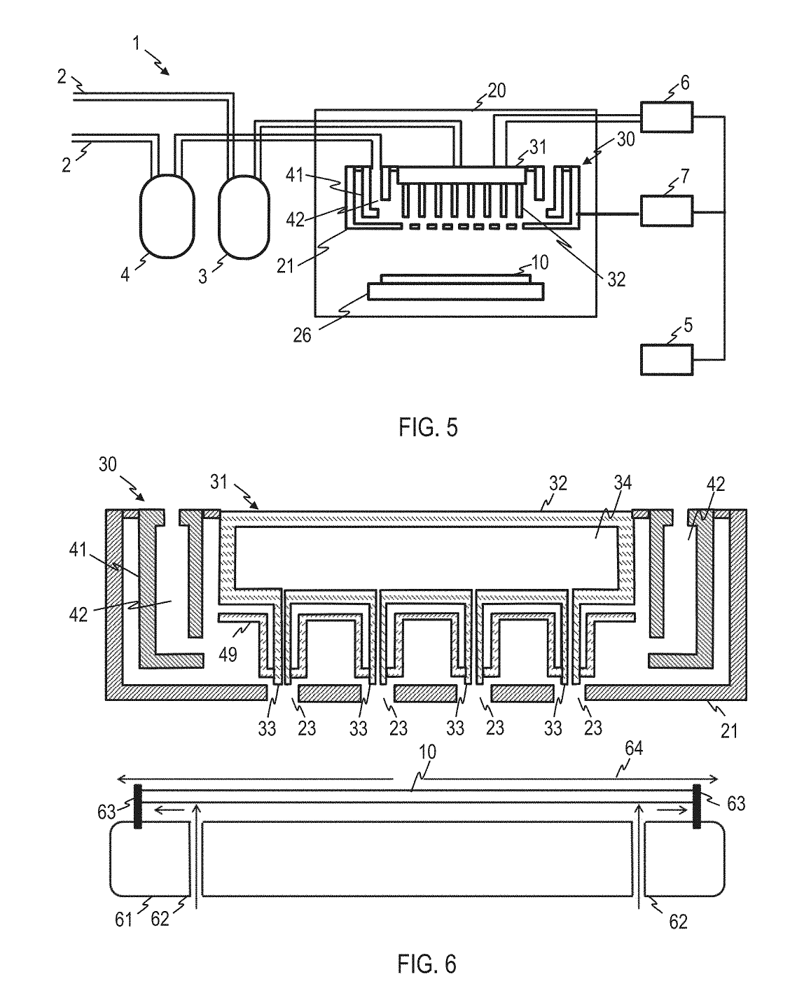

It will be appreciated that modifications of the embodiment explained with reference to FIG. 1 to FIG. 4 may be implemented in other embodiments. For illustration, at least one of the temperature adjustment mechanisms may be omitted. FIG. 5 illustrates a system 1 according to a preferred embodiment which comprises a gas injector 30, a control unit 5, and first and second temperature adjustment mechanisms 6, 7 which may be configured as explained with reference to FIG. 1 to FIG. 4 above. However, a heat sink 26 which may be a passive component may be provided to cool a surface of the substrate 10.

The system 1 depicted in FIG. 5 may have three or more gas conduits formed in the heat sink 26 or in another carrier. Gas flow through the three or more gas conduits formed in the heat sink 26 or in another carrier may cause levitation and rotation of the substrate 10 when etching of the substrate and/or deposition is performed.

The holder which holds the substrate 10 may comprise one, two, three or more than three holding members 9, as illustrated in FIG. 1. However, a gas injector comprising first and second flow paths and associated first and second temperature adjustment mechanisms may also be used with other substrate holding devices. For illustration, and as will be explained in more detail with reference to FIG. 6, FIG. 7, and FIG. 10 to FIG. 13, the system 1 may be configured to levitate and/or rotate the substrate 10 using a gas flow.

FIG. 6 is a schematic view of a system according to a preferred embodiment. Elements and features which may have a configuration and/or function that corresponds to that of elements and features explained with reference to FIG. 1 to FIG. 5 are designated with the same reference numerals. The system comprises a gas injector 30 having a first flow path 31 and a second flow path 41. The system comprises first and second temperature adjustment mechanisms 6, 7 which are independently operable and which may be associated with the first and second flow paths 31, 41, respectively.

The substrate 10 may be held at a distance from the top heater 21. To this end, the system may comprise a carrier 61 and gas conduits 62. The carrier 61 may have a substantially flat or specially profiled top surface. The carrier 61 may comprise holding members 63 which may be arranged at an outer edge of the substrate and/or a holding member located at a center position of the carrier 61. The carrier 61 may be a substrate bottom heater.

The holding member(s) 63 may hold the substrate 10 to prevent drifting of the substrate 10 while the substrate 10 is being rotated and levitated. That is, the holding member(s) 63 restrict movement of the substrate 10 during rotation and levitation. The holding member(s) 63 may restrict horizontal drifting of the substrate 10 during rotation and/or levitation. Various configurations of the holding member(s) may be used. For illustration, the holding member 63 may be a circular pin of a predetermined diameter so that the substrate 10 can be placed on top of the holding member 63. The holding member 63 may receive the substrate 10 at a center position thereof by penetrating through a predefined hole in the center of the substrate 10. The holding members 63 may be placed at an edge region of the substrate 10, as shown in FIG. 6. Although only two holding members 63 are visible in FIG. 6, three or more holding members 63 are generally provided in this case. In still further embodiments, a central holding member 65 may be provided in addition or as an alternative to the holding members 63, as will be explained with reference to FIG. 10 and FIG. 11.

The gas conduits 62 are located below the substrate at the carrier 61 and towards the edge of the substrate 10. When gas is provided from below the substrate 10, the substrate 10 may be elevated from its resting position. The gas flow through the gas conduits 62 is illustrated by the arrows below the substrate. Process gas 64 may be supplied through the gas injector 30 for a deposition and/or etching process applied to the wafers top surface.

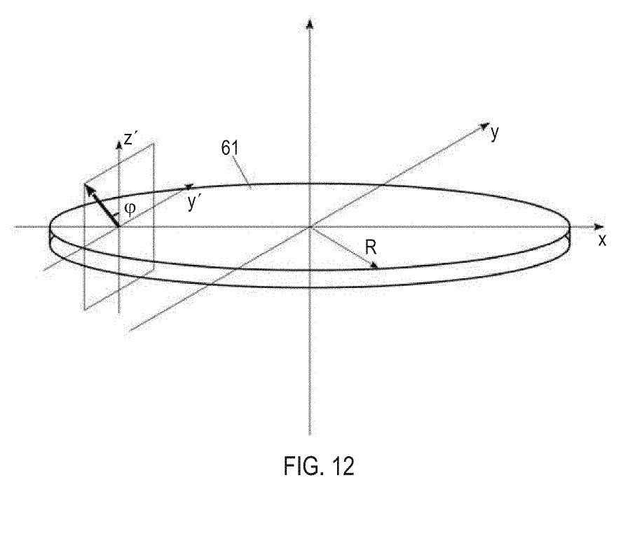

The gas conduits 62 may be arranged to have a substantially vertical direction. Alternatively, in order to rotate the substrate 10, the gas conduits 62 may respectively be arranged at an angle relative to the normal of the substrate 10 and at an angle relative to a circumferential vector of the carrier 61. As schematically illustrated in FIG. 7, the gas conduits 62 are configured to create a rotational effect in addition to the levitation effect, because they generate a gas flow which exerts a torque onto the substrate 10 to cause rotation of the substrate 10, as will be explained in more detail with reference to FIG. 12.

The inclined gas conduits 62 may lie within a plane defined by (i) a first vector which is normal to the substrate's radius or the carrier's radius and (ii) a second vector which lies within the bottom plane of the substrate or carrier and which is perpendicular to the substrate's radius or the carrier's radius at the position of the inclined gas conduit. I.e., the inclined gas conduits may extend generally parallel to a tangential plane to the carrier 61. The inclined gas conduits may be inclined with respect to a vector which is normal to the radius vector of the substrate or carrier and which lies within a plane of the bottom surface of the substrate or carrier.

As explained with reference to FIG. 2, the orifices 23 may have a center axis which is inclined relative to a normal direction of the substrate and/or the longitudinal axes of the gas outlets 33 may be inclined relative to the normal direction of the substrate. The orifices 23 and/or gas outlets 33 may be inclined to thereby attain a laminar flow at the substrate surface and/or to attain a uniform distribution of gas at the substrate. The utilization of the process media may be enhanced thereby.

In each one of the embodiments, the control unit 5 may control operation of at least one temperature adjustment mechanism 6, 7, 8 in a time-dependent manner. The time-dependent temperature change effected by the control unit 5 may be coordinated with a time-dependent variation in precursor supply. The control unit may cause a temperature of the substrate bottom heater 25 to vary in a manner which matches a pulsed precursor supply from the first flow path 31. The peaks in precursor supply and temperature of the substrate bottom heater 25 may assist in obtaining a higher quality layer at average lower substrate temperature. Such a process may also be referred to as “spike deposition”. The second temperature adjustment mechanism 7 may be controlled to provide fairly high, possibly even maximum, heating power. The pulsed operation in precursor supply and associated change in temperature of the substrate bottom heater 25 may be used for high temperature processes for the growth of special layers and for sensitive substrates which are incapable of withstanding the high temperatures for an extended time period. The pulsed operation allows the average sample temperature to be reduced.

A similar effect as described above can be used as process enabling feature for low temperature processes, where no deposition will take place below a threshold temperature level and only during the short pulses the temperature is made to exceed the threshold temperature. In this case, the second temperature adjustment mechanism 7 may be controlled such that a sufficient amount of activated precursor is provided to the surface.

FIG. 8 illustrates a pulsed supply 71 of precursor(s) through the first flow path 31. The control unit 5 may adjust the temperature of the substrate bottom heater 25 or of another heating mechanism in a manner which is coordinated, e.g., synchronized, with the peaks 72 in precursor supply. The temperature 73 of the substrate bottom heater 25 shows peaks 74 that provide sufficient energy for obtaining a higher quality layer, while the average substrate temperature may be kept at a lower value.

Modifications and alterations may be implemented in other embodiments. For illustration, the first flow path may comprise projections other than pins 33. When a first flow path comprising pins 33 or other projections is used, additional or alternative features may be implemented, as illustrated in FIG. 9.

FIG. 9 is a schematic cross-sectional view of a gas outlet 33 of a first flow path 31 of the gas injector 30. The gas outlet 33 is a pin-shaped projection and comprises an internal cavity delimited by an inner surface 91. The internal cavity extends to an outlet 35 along a longitudinal axis of the gas outlet 33. A bushing or sleeve 36 may be provided around at least a portion of the gas outlet 33 to reduce thermal coupling between the first flow path 31 and the second flow path 41. Alternatively or additionally, a reflective coating, e.g., a metal coating, may be provided on the outer surface of the gas outlet 33. The inner surface 91 of the gas outlet 33 may be polished to reduce adsorption and desorption.

An energy source may be comprised by or coupled to the gas outlet 33. The energy source may output electromagnetic radiation, e.g., light, for selective activation of certain regions of the substrate. The energy source may be an end of an optical fiber 37 or another element configured to output light. The energy source may also be provided remotely from the gas outlet 33, but the gas outlet 33 may be used to direct the energy output through the orifice 23 in the heater 21.

FIG. 10 is a schematic view of a system according to a preferred embodiment. Elements and features which may have a configuration and/or function that corresponds to that of elements and features explained with reference to FIG. 1 to FIG. 9 are designated with the same reference numerals. The system comprises a gas injector 30 having a first flow path 31 and a second flow path 41. The system comprises first and second temperature adjustment mechanisms 6, 7 which are independently operable and which may be associated with the first and second flow paths 31, 41, respectively.

The substrate 10 may be held at a distance from the top heater 21 and at a distance from the substrate bottom heater. To this end, the system may comprise a carrier 61 and gas conduits 62. The carrier 61 may have a substantially flat or specially profiled top surface. The carrier 61 may comprise a holding member 65 which may be located at a center position of the carrier 61. The carrier 61 may be a substrate bottom heater.

The holding member 65 may pass through a central opening in the substrate 10 to prevent drifting of the substrate 10 while the substrate 10 is being rotated and levitated. That is, the holding member 65 restricts movement of the substrate 10 during rotation and levitation. The holding member 65 may restrict horizontal drifting of the substrate 10 during rotation and levitation.

The gas conduits 62 are located below the substrate at the carrier 61 and may be arranged such that gas flow through the gas conduits causes levitation and rotation of the substrate 10. The gas conduits 62 may be arranged as explained with reference to FIG. 6.

FIG. 11 is a schematic top view of the substrate in a system according to a preferred embodiment. The system is configured to rotate and levitate the substrate during etching of the substrate and/or during deposition of one or plural layers onto the substrate 10. The system comprises both a holding member 65 arranged to pass through a central opening of the substrate 10 and a plurality of holding members 63 positioned around an edge 66 of the substrate.

Irrespective of whether the system comprises a central holding member 65 and/or plural holding members 63 positioned around the edge 66 of the substrate 10, the holding member(s) may respectively be operative to restrict drifting of the substrate 10 when the substrate is levitated. The holding members 63, 65 may have a cross-sectional area that increases towards the carrier 61. The holding members 63, 65 may be formed by plural cylinders stacked on top of each other to form a stepped surface. The holding members 63, 65 may be formed by a member having a conical or frustoconical outer surface. The holding members 63, 65 may be rotationally symmetric. The holding members 63, 65 may be attached to the carrier 61 so as to be non-rotatable relative to the carrier 61. Alternatively, the holding members 63, 65 may be attached to the carrier 61 so as to be rotatable relative to the carrier 61, e.g., by means of a ball bearing, roller bearing, gas bearing, or other bearing.

The holding members 63, 65 may have any one of a variety of configurations. For illustration, the holding member 63, 65 may comprise a plurality of cylindrical portions. A first cylindrical portion having a first diameter may be attached to or integrally formed with a second cylindrical portion having a second diameter larger than the first diameter. The holding member 63, 65 may be attached to the carrier 61 via a mount. The mount may attach the holding member 63, 65 to the carrier 71 in a torque-prove manner or may comprise a bearing to allow the holding member 63, 65 to rotate relative to the carrier 61.

During use, the substrate 10 may abut on a step surface formed at the transition between the first cylindrical portion and the second cylindrical portion of the holding member before the substrate 10 is levitated. When levitation of the substrate 10 is initiated, the substrate 10 may move out of abutment with the step surface formed at the transition between the first cylindrical portion and the second cylindrical portion. The system may be configured such that the substrate 10 is not lifted to a height higher than the top of the holding member. This ensures that the first cylindrical portion will remain positioned adjacent the substrate 10 so as to limit horizontal drifting thereof.

In other embodiments, the holding member 63, 65 may have a conical or frustoconical outer surface. During use, the substrate 10 may abut on the conical or frustoconical outer surface of the holding member 63, 65 prior to being levitated. When levitation of the substrate 10 is initiated, the substrate 10 may move out of abutment with the conical or frustoconical outer surface of the holding member 63, 65. The system may be configured such that the substrate 10 is not lifted to a height higher than the top of the holding member 63, 65. This ensures that the holding member 63, 65 will remain positioned adjacent the substrate 10 so as to limit horizontal drifting thereof.

As has been explained with reference to FIG. 6, FIG. 7, FIG. 10, and FIG. 11, at least three gas conduits may be provided in a substrate bottom heater or other carrier positioned below the substrate. Gas flow through the at least three gas conduits may be used to levitate the substrate 10 during etching of the substrate and/or layer deposition.

FIG. 12 shows the carrier 61 and a coordinate system, wherein the z-axis is the normal direction with respect to the carrier 61. The x- and y-axis are perpendicular to the z-axis and lie within the plane of the carrier 61. The x-axis is further defined by the location of the respective gas conduit. That is, the x-axis spreads along the diameter of the carrier 61 going through the location of the gas conduit. Furthermore, the x- and y-axis are perpendicular to each other.

In addition, FIG. 12 shows a plane which is defined by a vector z′ and a vector y′, wherein z′ is parallel to the z-axis and y′ is parallel to the y-axis. The inclination of the gas conduit is defined as the angle φ, i.e. the angle between a longitudinal axis of the gas conduit and the z′ direction, defined by the vector normal to the substrate bottom surface.

By the above definition, it is clear that the orientation of the y′- z′-plane depends on the location of the gas conduit. In other words, the orientation of the coordinate system depends on the location of the respective gas conduit.

Although the definition of the inclination angle φ of the gas conduits according to FIG. 12 is based on the relation of the carrier 61, the skilled person will appreciate that the same description may hold true with respect to the substrate 10. That is, the coordinate system in FIG. 12 may be defined with respect to the substrate 10 instead of the carrier 61.

The inclination angle φ may be between 2° and 60°, preferably between 5° and 50°, even more preferably between 10° and 45°. In exemplary embodiments, the inclination angle φ may be between 25° and 35° or between 28° and 32°. The inclination angle φ may be about 30°. Particularly effective levitation and rotation of the substrate 10 can be attained using an inclination angle φ in the indicated ranges.

The gas conduits 62 may be positioned on a circular line that is concentric with the carrier 61. A distance between each pair of next-neighbor gas conduits of the at least three gas conduits may be greater than 30% of a radius of the substrate, preferably greater than 50% of the radius of the substrate, more preferably greater than 70% of the radius of the substrate. The distance between each pair of next-neighbor gas conduits of the at least three gas conduits may be greater than 22.5 mm, preferably greater than 37.5 mm, more preferably greater than 52.5 mm, for example for a 6″ wafer.

Although the carrier 61 is illustrated in a circular shape, the carrier may have any kind of geometry. The same holds true for the substrate, which may have a circular or any other shape.

The system may in particular be adapted to rotate the substrate 10 with a rotational velocity between 60 rpm and 2000 rpm. The control unit 5 may be adapted to adjust a volume flow rate and/or flow velocity of the gas passed through each of the gas conduits 62 so as to attain a desired rotational velocity of the substrate 10. Closed-loop control may be used for that purpose. The actual, current rotational velocity of the substrate 10 may be sensed by a sensor coupled to the holding member(s) 63, 65 or using a rotational sensor separate from the holding member(s) 63, 65.

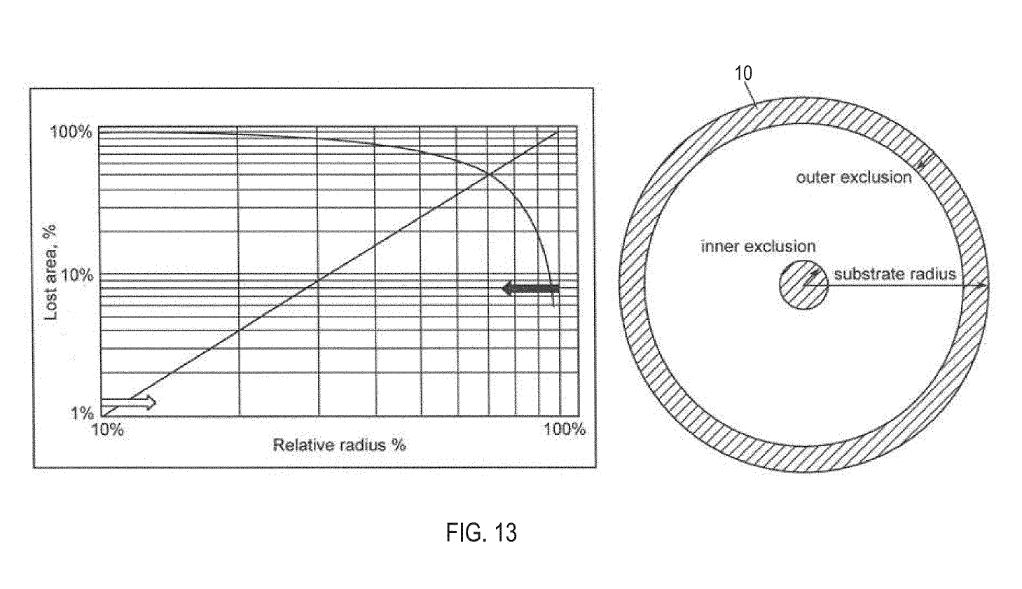

FIG. 13 illustrates the relationship between the lost area development for cutting the substrate from the center and the edge for comparison. That is, the area which is unusable after processing is illustrated depending on the use of a carrier according to the prior art (outer exclusion) or the use of a central holding member 65.

As can be seen from the graph in FIG. 13, the inner 10% of the radius represent negligible 1% of the surface area of the substrate. That is, a central holding member 65 causing a lost radius of 10% may lead to an unusable surface area of the substrate of 1%.

In contrast, the outer 10% ring (outer exclusion) represents 20% of the surface area of the substrate. That is, the inner exclusion area may be economically more valuable (by a factor of 10-50; factor 10 at 18% exclusion, factor 50 at 4%) compared to the outer exclusion area.

Furthermore, the central holding member 65 creates additional possibilities for the substrate handling and position adjustment for the equipment.

By levitating the substrate during etching of the substrate and/or deposition, various effects are attained. For illustration, a contactless treatment of a substrate can be performed in which no solid objects are in contact with the major surfaces of the substrate 10. Undesired temperature variations along the substrate surface and/or shorter ramping times can be attained thereby. This improves process control.

The gas conduits provided in the carrier, which may be a substrate bottom heater, are gas inlets through which gas is passed to the bottom surface of the substrate.

While embodiments have been described with reference to the drawings, alterations and modifications may be implemented in other embodiments. For illustration, while certain configurations of the first and second flow path have been described, modifications may be implemented in other embodiments. The first flow path does not need to comprise pins, but may also have other configurations. The channels through which the second group of process gases is passed through the second flow path do not need to be arranged circumferentially around the first flow path. Rather, channels in which cool first group of process gases is guided and channels in which a warmer second group of process gases is guided may be arranged so as to be interspersed with each other. While a gas injector according to a preferred embodiment may be used to provide different first and second group of process gases to the substrate, the gas injector may also be used for depositing only one precursor gas or only one reactant gas which is passed through the different fluid paths. The systems and methods according to embodiments may be used for gas phase deposition on a substrate which may be a wafer, without being limited thereto. Gas injectors affording independent temperature control of a first flow path and a second flow path may be arranged on each one of two opposing sides of the substrate. The first and second flow paths of one gas injector may also be arranged on opposite sides relative to the substrate. Gas injectors and/or heaters may be arranged on both sides of the substrate.

Systems and methods according to embodiments may be used for gas phase deposition in Metalorganic Vapour Phase Epitaxy (MOVPE) or Metalorganic Chemical Vapour Deposition (MOCVD), without being limited thereto.

1. A system for gas phase deposition, comprising:
a gas injector configured to guide process gases to a substrate for gas phase deposition onto the substrate, the gas injector comprising a first flow path and a second flow path different from the first flow path;
a first temperature adjustment mechanism associated with the first flow path to control a temperature of a process gas passing through the first flow path; and
a second temperature adjustment mechanism associated with at least the second flow path to control a temperature of a process gas passing through the second flow path, the first temperature adjustment mechanism and the second temperature adjustment mechanism being operable independently of each other;
wherein the system is configured to cause rotation and levitation of the substrate during etching of the substrate and/or deposition.

2. The system of claim 1, further comprising:
a third temperature adjustment mechanism configured to heat or cool the substrate from at least one surface of the substrate,
optionally wherein the third temperature adjustment mechanism is operable independently of the first temperature adjustment mechanism and the second temperature adjustment mechanism.

3. The system of claim 2, wherein the second temperature adjustment mechanism is configured to heat the substrate from a first surface of the substrate and the third temperature adjustment mechanism is configured to heat or cool the substrate from a second surface of the substrate, the second surface being opposite the first surface.

4. The system of claim 2, wherein the third temperature adjustment mechanism comprises a substrate bottom heater and the system comprises a control unit configured to cause a heater temperature of the substrate bottom heater to change as a function of time in a manner coordinated with a time-dependent variation of a flow of a process gas through the first flow path.

5. The system of claim 1, wherein at least one gas diffuser is arranged in a channel of the second flow path and/or wherein the system comprises a reactor selected from a group consisting of a hot wall reactor, a cold wall reactor, and a reactor controllable to perform cold wall reactor operation and hot wall reactor operation in a time-sequential manner.

6. The system of claim 1, wherein the first flow path comprises a plurality of projections respectively extending along a longitudinal axis, each one of the plurality of projections respectively having an internal cavity extending along the longitudinal axis to pass the process gases through the respective projection and an outlet opening.

7. The system of claim 6, wherein the first flow path further comprises a member having at least one internal cavity in communication with the cavities of the plurality of projections, the plurality of projections projecting from a major face of the member and being thermally coupled to the member.

8. The system of claim 7, wherein the projections are gas outlets projecting from the member, the gas outlets having an inner diameter of at least 0.1 mm and at most 1 mm and/or the gas outlets being arranged on the major face of the member at a surface density of at least 0.1 cm⁻² and at most 20 cm⁻².

9. The system of claim 8, wherein
the gas outlets have a polished inner surface and/or
the gas outlets have an outer surface which is polished or provided with a reflective metal coating.

10. The system of claim 7, wherein the projections extend parallel to a normal direction of the major face of the member.

11. The system of claim 7, wherein the projections are inclined relative to a normal direction of the major face of the member.

12. The system of claim 6, wherein the projections are arranged in a regular pattern, a square pattern, a circular pattern, or a circular pattern comprising a plurality of concentric circles.

13. The system of any claim 6, wherein the projections comprise at least a first set of gas outlets and a second set of gas outlets to introduce different process gases, the first set of gas outlets and the second set of gas outlets being arranged in a interlaced pattern.

14. The system of claim 6, wherein the first flow path comprises at least one duct for a coolant or heating agent and the first temperature adjustment mechanism is configured to pass the coolant or heating agent through the at least one duct.

15. The system of claim 6, further comprising:
a heat insulator or heat shield interposed between the plurality of projections and at least a portion of the second flow path.

16. The system of claim 6, wherein the second flow path comprises a plurality of channels disposed radially outward of the plurality of projections.

17. The system of claim 1, wherein the second temperature adjustment mechanism comprises a heater having orifices arranged to allow the process gases from both the first flow path and the second flow path to pass through the orifices to the substrate, and/or
wherein the system is configured to pass a first group of process gases through the first flow path at a first flow velocity and to pass a second group of process gases through the second flow path (41) at a second flow velocity which is less than the first flow velocity, the second group of process gases being different from the first group of process gases.

18. The system of claim 17, wherein the orifices have center axes which are inclined relative to a normal of a substrate surface or wherein the orifices have center axes which parallel to the normal of the substrate surface.

19. The system of claim 1, wherein the system comprises at least two gas conduits in a carrier to provide gas to a bottom surface of the substrate to levitate the substrate above the carrier.

20. A gas phase deposition method, comprising:
passing a first group of process gases through a first flow path of a gas injector to a substrate;
passing a second group of process gases through a second flow path of the gas injector, the second flow path being different from the first flow path 31 and the second group of process gases being different from the first group of process gases;
controlling a first temperature adjustment mechanism associated with the first flow path to control a temperature of the first group of process gases passing through the first flow path;
controlling a second temperature adjustment mechanism associated with at least the second flow path to control a temperature of the second group of process gases passing through the second flow path, the first temperature adjustment mechanism and the second temperature adjustment mechanism being operable independently of each other; and
wherein the substrate is rotated and levitated during etching of the substrate and/or deposition.

21. The system of claim 1, wherein the process gases respectively comprise reactants, precursors, or a mixture of reactants or precursors, with or without a carrier gas.

22. The method of claim 20, wherein the process gases respectively comprise reactants, precursors, or a mixture of reactants or precursors, with or without a carrier gas.
